(19) United States
(12) Patent Application Publication
(10) Pub. No.: US 2012/0229964 A1
(43) Pub. Date: Sep. 13, 2012

(54) SUPPORT MECHANISM AND ELECTRONIC DEVICE USING SAME

(75) Inventors: BIN DU, Shenzhen City (CN); WEN-RONG CHEN, Tu-Cheng (TW); HUI LI, Shenzhen City (CN); CONG HUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/207,999

(22) Filed: Aug. 11, 2011

(30) Foreign Application Priority Data
Mar. 10, 2011 (CN) 201110057305.2

(51) Int. Cl. H05K 7/00; F16M 11/20

(52) U.S. Cl. 361/679.01; 248/188.6

(57) ABSTRACT

A support mechanism includes a securing element comprising a main body, a hook extending from the main body and a securing groove formed between the hook and the main body; a support element hinged to the main body.

### BACKGROUND

1. Technical Field

The exemplary disclosure relates to support mechanisms, particularly to support mechanisms used in electronic devices.

2. Description of Related Art

Some portable electronic products have a bracket on the back of its casing. Thus, when the bracket is opened, the portable electronic product becomes supported and able to sit on the desk or other supporting surface to make it more comfortable for the users to view the displays. Folding the bracket flush with the back of the unit makes them more convenient to carry.

However, typical brackets of the existing portable electronic products have a complicated structure and are difficult to manufacture and use.

Therefore, there is room for improvement within the art.

### BRIEF DESCRIPTION OF THE DRAWINGS

Many aspects of the exemplary support mechanism and electronic device using the support mechanism can be better understood with reference to the following drawings. These drawings are not necessarily drawn to scale, the emphasis instead being placed upon clearly illustrating the principles of the present support mechanism and electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of a support mechanism according to an exemplary embodiment.

FIG. 2 is a schematic view of an electronic device with the support mechanism in a closed position.

FIG. 3 is similar to the FIG. 2, showing the support mechanism in an open position.

### DETAILED DESCRIPTION

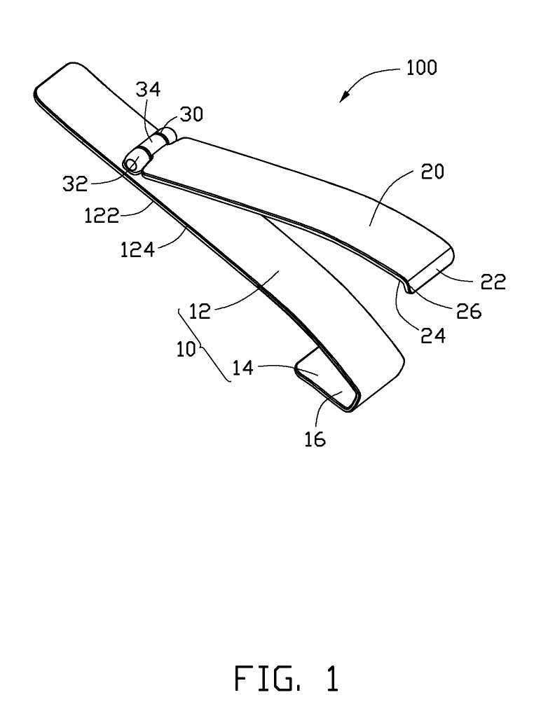

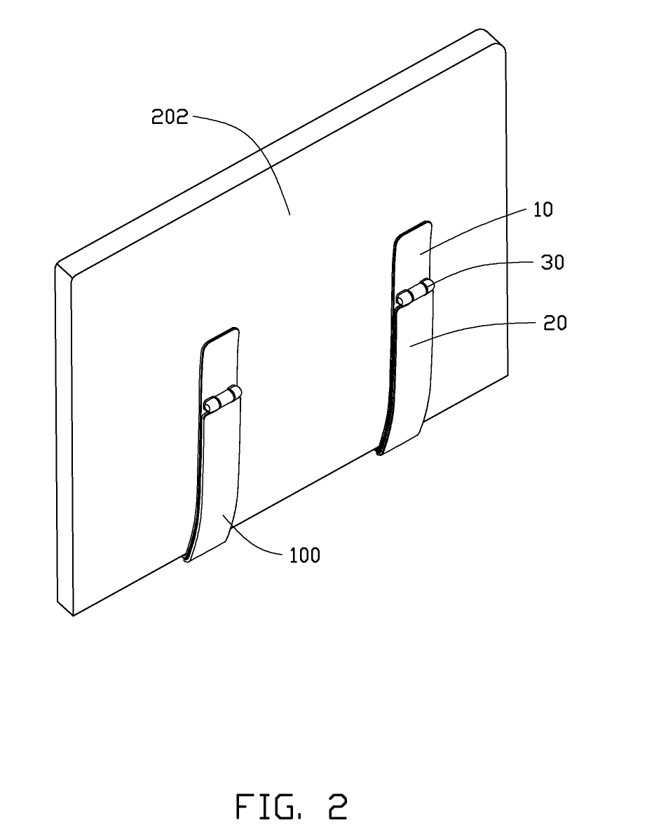

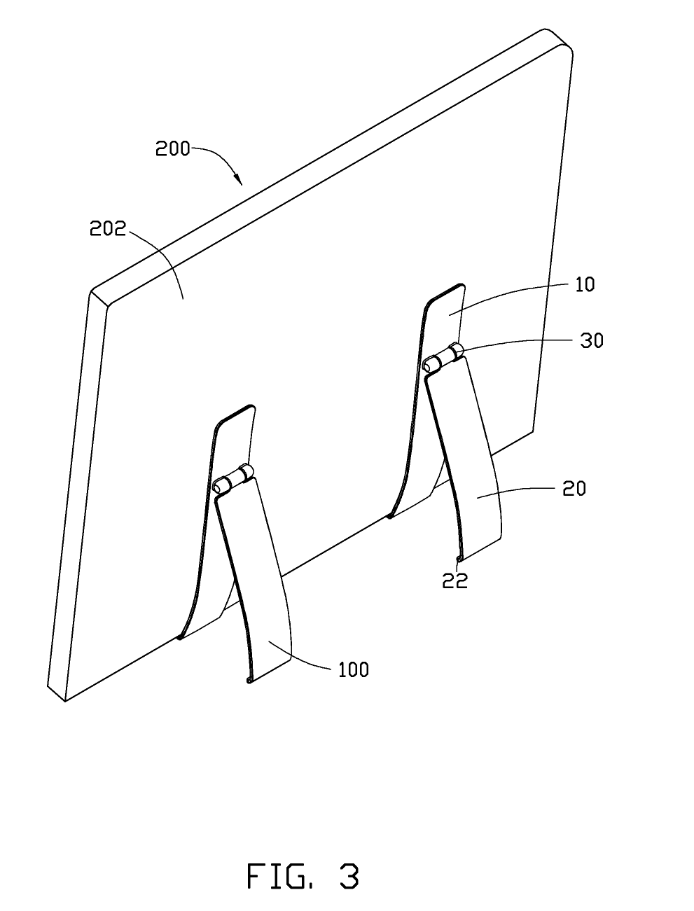

An embodiment of an electronic device 200 incorporating a support mechanism 100 is shown in FIGS. 1 to 3. FIG. 1 illustrates the support mechanism 100 in an open state. FIGS. 2 and 3 illustrate the electronic device 200 with the support mechanism 100 in closed and opened states. The electronic device 200 includes a housing 202. The support mechanism 100 includes a securing element 10 and a support element 20 hinged to the securing element 10. The securing element 10 comprises a metal layer 122 and a rubber layer 124 formed on the metal layer 124. The metal layer 11 meets a structural strength requirement of the securing element 10. The rubber layer 124 prevents the electronic device 200 from damage when the electronic device is secured in the securing element 10. The support element 20 comprises a metal layer 24 and a rubber layer 26. The metal layer 24 meets a structural strength requirement of the support element 20. The rubber layer 26 prevents a user of the electronic device 200 from being hurt.

The securing element 10 is resilient and includes a main body 12, a hook 14, for example, L-shaped, extending from one end of the main body 12, and a securing groove 16 defined between the main body 12 and the hook 14. The securing groove 16 is thinner than the electronic device 200 so the housing 202 can be tightly secured in the securing groove 16 and supported by the rubber after the hook 14 is opened elastically

In this exemplary embodiment, the support element 20 is hinged to the main body 12 by a hinge 30. The hinge 30 includes a retaining portion 32 and a rotation portion 34 hinged to the retaining portion 32. The retaining portion 32 is retained on the main body 12 and the rotation portion 34 is retained on the support element 20 so the support element 20 can rotate relative to the securing element 10 around the hinge 30. The hinge 30 may be a friction hinge, which can provide any angle of support between the support element 20 and the securing element 10. When the support mechanism 100 is in a closed state like shown FIG. 1, the support element 20 and the securing element 10 are formed to make them more convenient to carry.

Referring to FIGS. 2 and 3, in use, at least one support mechanism 100 is used to support the housing 202. In this exemplary embodiment, two support mechanisms 100 are used to illustrate operation of the support mechanism 100. The hooks 14 are opened to allow two portions of the housing 202 to be inserted into the securing grooves 16. The hooks 14 are released so the hooks 14 are closed to secure the portions of the housing 202 in the securing grooves 16 with the main bodies 12 resisting a back surface of the housing 202. Then, a user can adjust the hinges 30 to adjust the angle of the support elements 20 relative to the securing elements 10 until the housing 202 is at a comfortable viewing angle, such as shown in FIG. 3.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A support mechanism, comprising:
a securing element comprising a main body, a hook extending from the main body and a securing groove formed between the hook and the main body; and
a support element hinged to the main body.

2. The support mechanism of claim 1, wherein the hook is L-shaped.

3. The support mechanism of claim 1, wherein one end of the support element is bent to form a support plate, the other end is hinged to the main body.

4. The support mechanism of claim 1, further comprising a hinge hinging the support element to the main body.

5. The support mechanism of claim 4, wherein the hinge is a friction hinge, which can provide any angle between the support element and the securing element.

6. The support mechanism of claim 1, wherein the securing element is formed by a metal plate and a soft rubber plate.

7. The support mechanism of claim 1, wherein the support element is formed by a metal plate and a soft rubber plate.

8. An electronic device, comprising:
a housing;
a securing element comprising a main body, a hook extending from the main body and a securing groove formed between the hook and the main body; and
a support element hinged to the main body;
wherein the housing is secured in the securing groove.

9. The electronic device of claim 8, wherein the hook is L-shaped.

10. The electronic device of claim 8, wherein one end of the support element is bent to form a support plate, the other end is hinged to the main body.

11. The electronic device of claim 8, further comprising a hinge hinging the support element to the main body.

12. The electronic device of claim 11, wherein the hinge is a friction hinge, which can provide any angle between the support element and the securing element.

13. The electronic device of claim 8, wherein the securing element is formed by a metal plate and a soft rubber plate.

14. The electronic device of claim 8, wherein the support element is formed by a metal plate and a soft rubber plate.

15. The electronic device of claim 8, wherein the securing groove is thinner than the electronic device so the housing can be tightly secured in the securing groove after the hook is opened elastically.
